(19) United States
(12) Patent Application Publication
(10) Pub. No.: US 2012/0161175 A1
(43) Pub. Date: Jun. 28, 2012

(54) VERTICAL STRUCTURE LIGHT EMITTING DIODE AND METHOD OF MANUFACTURING THE SAME

(75) Inventors: Shiue-Lung CHEN, Taoyuan (TW); Jeng-Guo Feng, Taoyuan (TW); Cang-Ho Chen, Taoyuan (TW); Ching-Hwa Chang Jean, Taoyuan (TW)

(73) Assignee: WALSIN LIHWA CORPORATION, Taoyuan (TW)

(21) Appl. No.: 12/978,696

(22) Filed: Dec. 27, 2010

(51) Int. Cl. H01L 33/60; H01L 33/40

(52) U.S. Cl. 257/98; 438/29; 257/E33.072; 257/E33.061

(57) ABSTRACT

A vertical structure light emitting diode (LED) and a method of manufacturing the same are disclosed. The vertical structure LED includes a metal layer as an electrode; a number of luminescent layers formed on the metal layer for providing light beams; a spreading layer formed on the luminescent layers; a medium layer provided on the spreading layer, having an opening formed therethrough to expose the spreading layer and a roughed surface. The spreading layer facilitates diffusion of current produced by the electrode.

### FIELD OF THE INVENTION

The present invention relates generally to a method of manufacturing a vertical structure light emitting diode (LED). More specifically, the present invention relates to a method of manufacturing a vertical structure light emitting diode (LED) having several stop layers created before formation of a n-GaN layer to restrain threading dislocation caused during epitaxy of a u-GaN layer on a sapphire substrate so that the yield rate thereof can be improved while laser lift-off (LLO) process is introduced and throughput of the LED can be raised.

### BACKGROUND OF THE INVENTION

Heat dissipation management is the main issue on the development for packaged high power LEDs under high current driving. For a lateral current conducting structure epitaxially formed on a sapphire substrate, there are drawbacks on the current crowding effect, high series resistance and poor heat dissipation.

The disadvantage of poor heat sink of sapphire can be resolved by other heat dissipation substrate by laser lift-off (LLO) process using a short wavelength excimer source. For example, U.S. Pat. No. 7,384,807 to Yoo disclosed a method of fabricating a vertical structure opto-electronic device which includes fabricating a plurality of vertical structure opto-electronic devices on a crystal substrate, and then removing the substrate using a laser lift-off process. However the electrical and optical properties of LEDs are dependent on crystal quality of the epitaxial layers which are subject to additional chemical process (e.g. etching), mechanical process (e.g. lapping), and laser lift-off process. It may be needed for laser beam to scan an epitaxial wafer more than one time, which decreases the throughput and increases the chance of damaging the epitaxial layers of LEDs. Also, the laser lift-off equipment is expensive.

In order to achieve a high yield of LLO process, it is necessary to separate the island of epi-GaN by chemical or physical etching process to form a heat exhaustion structure (so called “street path”). The street path has a benefit of nitrogen gas release during LLO process to achieve high yield.

However, due to an increased dimension of the epi-GaN island, it is necessary to enlarge width of the street path to avoid adjacent islands from attack by the pressure of nitrogen released from photo-induced decomposition.

Sapphire (Al₂O₃) is the most popular substrate for epitaxial growth of AlInGaN-based materials in light emitting diodes (LEDs) manufacturing. However, the thermal conductivity of the sapphire substrate is not so good that the blue light emitting diode is limited to a lateral conducting structure with its positive and negative metal electrodes on the same side of the substrate. Thus, the structure substantially shrinks the lighting area. Besides, due to current crowding effect and lateral path, there are inevitable increases in series resistance (Rs) and forward voltage drop (Vf) of the LED device. The huge amount of heat generated decays external quantum efficiency directly.

Substituting a traditional sapphire substrate for a heat dissipation substrate by using excimer laser lift-off (LLO) technology has been used for many years. Although it is commercialized, the manufacturing cost of such LED device is still quite expensive due to its complex processes and low yield. According to the high bandgap energy of sapphire, a short wavelength (<355 nm) excimer laser beam can penetrate the polished sapphire substrate and be absorbed in the interface between sapphire and the epitaxial buffer layer (u-GaN). The absorbed energy is accumulated on the surface of u-GaN and converted to heat energy which allows u-GaN to be gasified and nitrogen gas to be released. Subsequently, the released nitrogen gas may cause damage to neighboring insolated epitaxial elements and the heat dissipation substrate due to the pressure thus formed. Therefore, the peeling of the fragile interface formed by bonding or electroplating technology may produce the issue on reliability, for example, fast degradation of light output power, increase of forward voltage drop after package.

In order to solve the problem mentioned above and increase yield rate of the excimer laser lift-off process, the inventor has provided a vertical structure light emitting diode (LED) having a duct and a number of gaps for heat exhaustion, as described in U.S. application Ser. No. 12/634,747 filed on Dec. 10, 2009. A buffer layer is provided to form a number of air gaps between the sapphire substrate and the buffer layer. The structure can dissipate heat caused by current crowding effect via the air gaps. Furthermore, a duct between any two LED semi-products helps heat dissipation as well. The key in the previous invention is to make the buffer layer recessed to accommodate protrusions on the sapphire substrate. It takes more cost to design and get a better combination for the buffer layer and the sapphire substrate. New epitaxial layers are formed on the sapphire substrate for increasing yield rate of the excimer laser lift-off process. No special designs are required and threading dislocation is utilized which is considered as a defect for LEDs.

### SUMMARY OF THE INVENTION

This paragraph extracts and compiles some features of the present invention; other features will be disclosed in the follow-up paragraphs. It is intended to cover various modifications and similar arrangements included within the spirit and scope of the appended claims.

In accordance with an aspect of the present invention, a manufacturing method of a vertical structure light emitting diode (LED), includes: a) forming a chemical resistant layer, a medium layer and a spreading layer on a substrate in sequence; b) growing a plurality of luminescent layers on the spreading layer; c) removing the substrate and the chemical resistant layer; d) upturning the remaining layers enabling the medium layer as a top layer; e) roughening a surface of the medium layer; and f) setting a metal layer under the luminescent layers as an electrode.

In accordance with another aspect of the present invention, a vertical structure light emitting diode (LED) includes a metal layer as an electrode; a plurality of luminescent layers formed on the metal layer for providing light beams; a spreading layer formed on the luminescent layers; a medium layer provided on the spreading layer, having an opening formed therethrough to expose the spreading layer and a roughed surface.

### BRIEF DESCRIPTION OF THE DRAWINGS

FIGS. 1 to 8 illustrate manufacture of a vertical structure LED according to the present invention.

### DETAILED DESCRIPTION OF THE PREFERRED EMBODIMENT

In order to increase yield rate of laser lift-off (LLO), an improved vertical structure light emitting diode is desired. An embodiment of the present invention showing a method of manufacturing a vertical structure light emitting diode is described below.

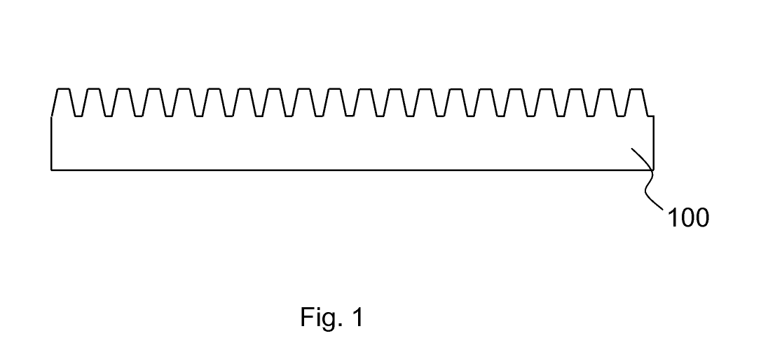

Please refer to FIGS. 1 to 8. Formation of a vertical structure LED according to the present invention is illustrated. In this embodiment, a substrate 100, such as a sapphire substrate or a patterned sapphire substrate or a high density patterned sapphire substrate for forming epitaxially grown LED luminescent layers, is provided. In this embodiment, the substrate 100 is a patterned sapphire substrate as shown in FIG. 1. The sizes of the patterns of the substrate 100 are similar and disposed continuously or closely to each other.

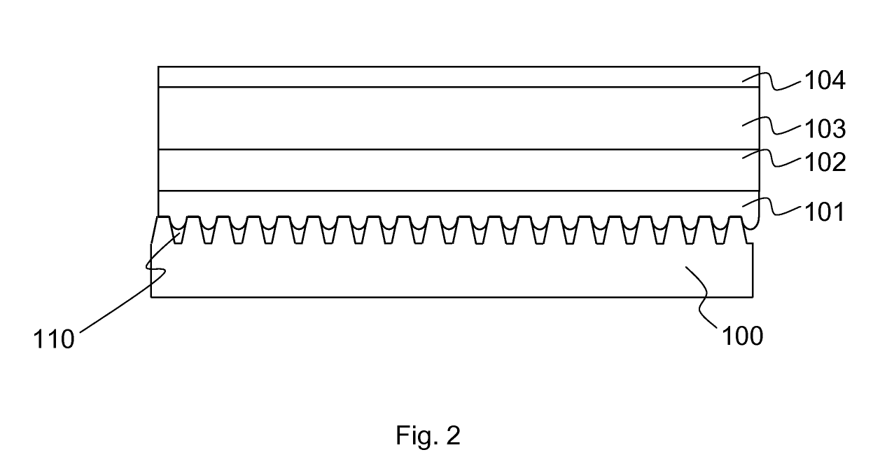

Please refer to FIG. 2, a sacrificial layer 101 is formed on the substrate 100 first, and then a chemical resistant layer 102, a medium layer 103 and a spreading layer 104 are formed on the substrate 100 in sequence. Those layers can be formed by metallic organic chemical vapor deposition (MOCVD). The sacrificial layer 101 is lightly doped and the spreading layer 104 is heavily doped. In other words, doping of the spreading layer 104 is heavier than that of the sacrificial layer 101. A number of air gaps 110 are formed between the substrate 100 and the sacrificial layer 101 for heat exhaustion, as shown in FIG. 2. This is due to threading dislocation phenomenon. Dislocation of epitaxial molecules forms the air gaps. Details for formation of the air gaps 110 are described in the co-pending case, which is commonly assigned U.S. application Ser. No. 12/634,747 filed on Dec. 10, 2009.

The chemical resistant layer 102 can block any chemical etching process used in producing luminescent layers. Therefore, the medium layer 103 can be preserved. It should be noticed that the sacrificial layer 101 or the chemical resistant layer 102 or the medium layer 103 or the spreading layer 104 is n type gallium nitride (n-GaN) in the present invention.

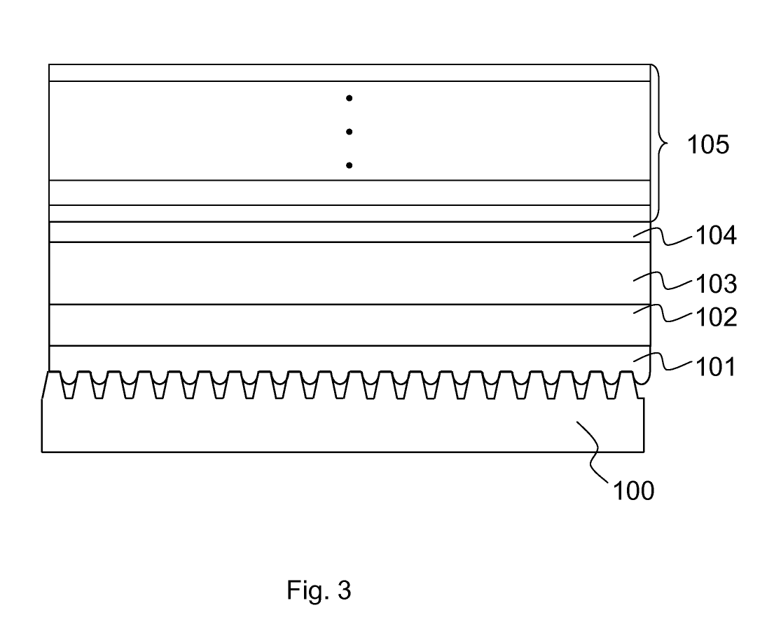

After, a number of luminescent layers 105 are formed on the medium layer 104 as shown in FIG. 3. The luminescent layers 105 may include a lightly doped n-GaN layer, a strained layer, a multiple quantum well (MQW), an electron blocking layer (EBL), a p type gallium nitride (p-GaN) layer, etc., with different lightening degree and color requirement.

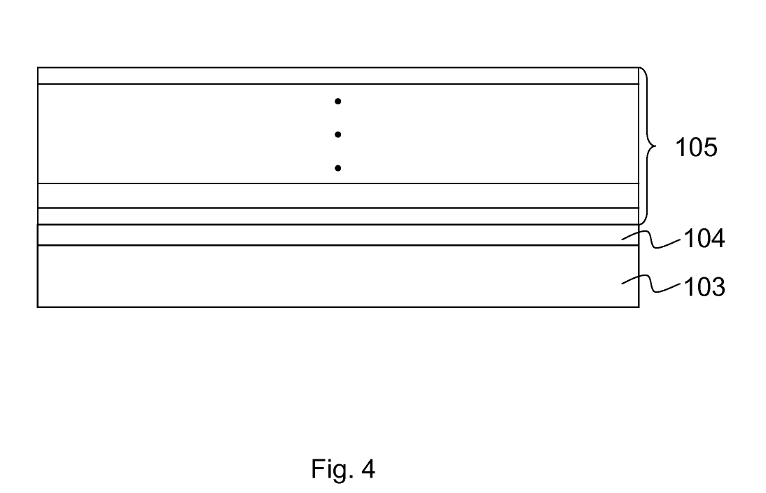

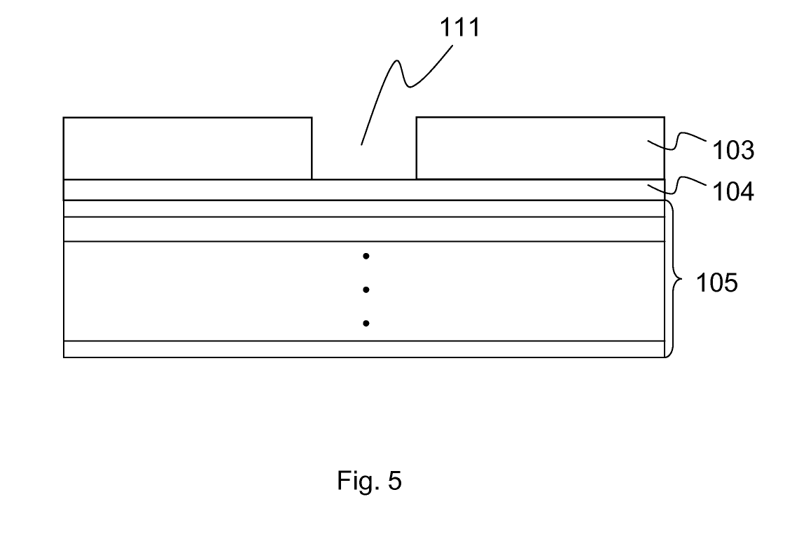

Please refer to FIG. 4, the sapphire substrate 100, the sacrificial layer 101, and the chemical resistant layer 102 are removed before forming electrodes. The method of removing the above layers includes excimer laser lift-off (LLO), dry etching, physical etching, and chemical etching. The gasified nitrogen and heat generated by LLO would be dissipated by the air gaps 110 formed between the substrate 100 and the sacrificial layer 101. Later, the remaining layers 103, 104 and 105 are upturned enabling the medium layer 103 as a top layer, and then the medium layer 103 is etched through to form an opening 111 for heat exhaustion until a portion of the spreading layer 104 is exposed, as shown in FIG. 5. The etching method can be inductively coupled plasma (ICP) dry etching, sputter etching, ion beam etching or plasma etching.

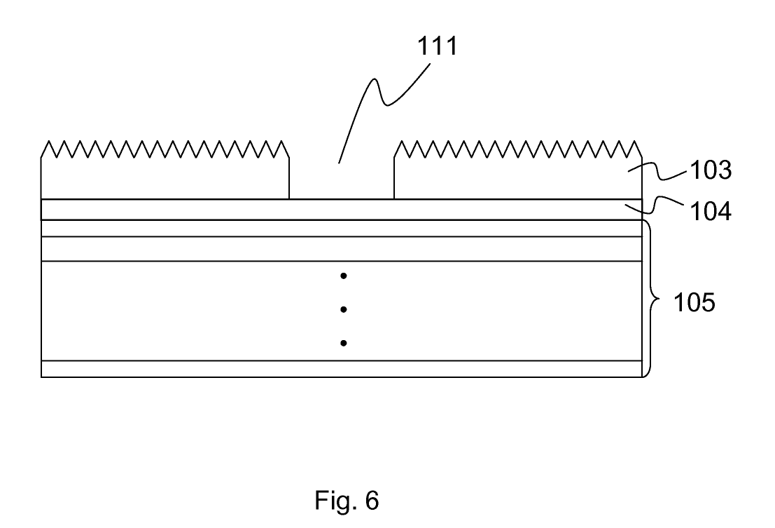

Next, in order to enhance light extraction of the vertical structure LED, a surface of the medium layer 103 is roughened, as shown in FIG. 6. In this embodiment, the roughened surface of the medium layer 103 can be formed by dry etching or wet etching.

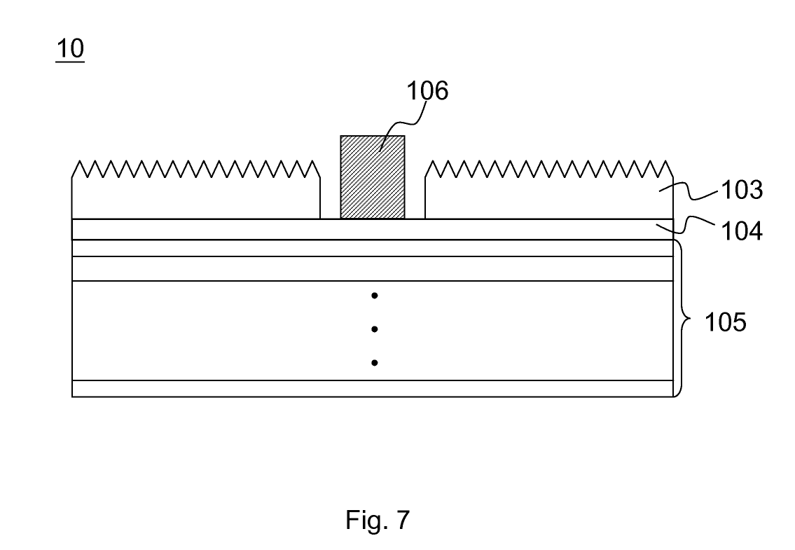

Furthermore, an electrode 106 can be deposited in the opening 111 on the spreading layer 104, as shown in FIG. 7. Of course, the number of electrode 106 is not limited to 1. Depending on requirement, the number can be increased.

It should be noticed that the chemical resistant layer 102 can reduce threading dislocations of the substrate 100 extended into the luminescent layers 105. The spreading layer 104 facilitates diffusion of current produced by the electrode 106. Besides, the sacrificial layer 101 and the medium layer 103 have higher threading dislocation densities. The chemical resistant layer 102 and the spreading layer 104 have lower threading dislocation densities. In other words, threading dislocation densities of the sacrificial layer 101 or the medium layer 103 is higher than that of the chemical resistant layer 102 or the spreading layer 104.

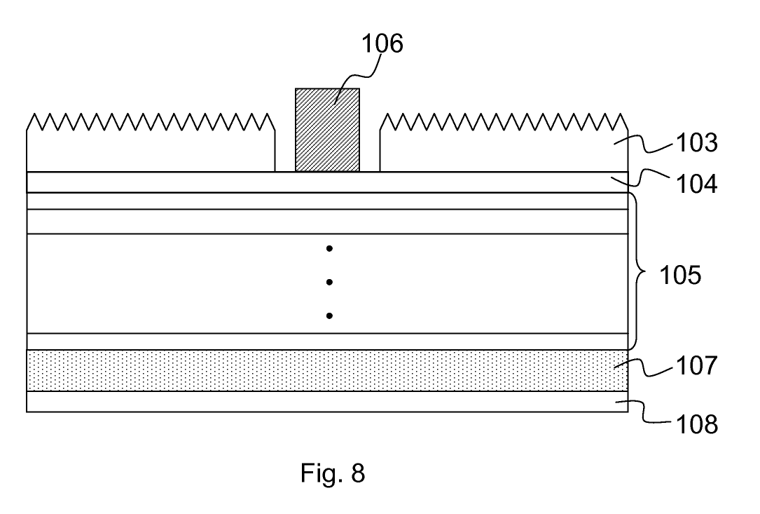

Finally, an agglutinate layer 107 is added below the luminescent layers 105 for adhering a metal layer 108 under the luminescent layers 105, as shown in FIG. 8. The metal layer 108 can be used as an electrode. Furthermore, a reflective layer can be placed between the metal layer 108 and the luminescent layers 105 for enhancing light extraction of the vertical structure LED chip 10. Alternatively, reflective materials can be added to the agglutinate layer 107 such that the agglutinate layer 107 can also act as a reflective layer.

Please refer to FIG. 8. According to the method for manufacturing a vertical structure LED of the present invention, a final vertical structure LED chip 10 includes a number of luminescent layers 105 for providing light beams, a spreading layer 104 formed on the luminescent layers 105 for diffusing current, a medium layer 103 provided on the spreading layer 104 which has an opening 111 formed therethrough and a roughed surface for enhancing light extraction of the vertical structure LED chip 10, and an electrode 106 placed in the opening 111 on the spreading layer 104. Moreover, an agglutinate layer 107 is added below the luminescent layers 105 for adhering a metal layer 108 under the luminescent layers 105.

While the invention has been described in terms of what is presently considered to be the most practical and preferred embodiment, it is understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A manufacturing method of a vertical structure light emitting diode (LED), comprising:
a) forming a chemical resistant layer, a medium layer and a spreading layer on a substrate in sequence;
b) growing a plurality of luminescent layers on the spreading layer;
c) removing the substrate and the chemical resistant layer;
d) upturning the remaining layers enabling the medium layer as a top layer;
e) roughening a surface of the medium layer; and
f) setting a metal layer under the luminescent layers as an electrode.

2. The manufacturing method of claim 1, wherein the substrate is a patterned substrate.

3. The manufacturing method of claim 1, further comprising a step of forming a sacrificial layer on the substrate before forming the chemical resistant layer.

4. The manufacturing method of claim 1, further comprising:
etching through the medium layer as an opening to expose the spreading layer; and
placing another electrode in the opening.

5. The manufacturing method of claim 1, wherein an agglutinate layer is formed between the metal layer and the luminescent layers.

6. The manufacturing method of claim 1, wherein a reflective layer is formed between the metal layer and the luminescent layers.

7. The manufacturing method of claim 6, wherein the agglutinate layer is a reflective layer.

8. The manufacturing method of claim 1, wherein step c) is performed by excimer laser lift-off (LLO), dry etching or chemical etching.

9. The manufacturing method of claim 1, wherein steps a) is performed by metallic organic chemical vapor deposition (MOCVD).

10. The manufacturing method of claim 3, wherein the sacrificial layer or the chemical resistant layer or the medium layer or the spreading layer is n type gallium nitride (n-GaN).

11. The manufacturing method of claim 3, wherein threading dislocation densities of the sacrificial layer or the medium layer is higher than that of the chemical resistant layer or the spreading layer.

12. The manufacturing method of claim 4, wherein the etching step is performed by inductively coupled plasma (ICP) dry etching, sputter etching, ion beam etching or plasma etching.

13. The manufacturing method of claim 3, wherein doping of the spreading layer is heavier than that of the sacrificial layer.

14. A vertical structure light emitting diode (LED), comprising:
a metal layer as an electrode;
a plurality of luminescent layers formed on the metal layer for providing light beams;
a spreading layer formed on the luminescent layers; and
a medium layer provided on the spreading layer, having an opening formed therethrough to expose the spreading layer and a roughed surface.

15. The vertical structure LED of claim 14, further comprising another electrode placed in the opening.

16. The vertical structure LED of claim 14, further comprising an agglutinate layer formed between the metal layer and the luminescent layers.

17. The vertical structure LED of claim 16, wherein the agglutinate layer is a reflective layer.

18. The vertical structure LED of claim 14, further comprising a reflective layer formed between the metal layer and the luminescent layers.

19. The vertical structure LED of claim 14, wherein the spreading layer or the medium layer is n type gallium nitride (n-GaN).

20. The vertical structure LED of claim 14, wherein threading dislocation density of the medium layer is higher than that of the spreading layer.
